(19) United States
(12) Patent Application Publication
(10) Pub. No.: US 2025/0252017 A1
(43) Pub. Date: Aug. 7, 2025

(54) SEMICONDUCTOR DEVICE AND SEMICONDUCTOR SYSTEM

(71) Applicant: SK hynix Inc., Icheon-si Gyeonggi-do (KR)

(72) Inventor: Joon Yong CHOI, Icheon-si Gyeonggi-do (KR)

(73) Assignee: SK hynix Inc., Icheon-si Gyeonggi-do (KR)

(21) Appl. No.: 19/018,100

(22) Filed: Jan. 13, 2025

(30) Foreign Application Priority Data
Feb. 7, 2024 (KR) 10-2024-0019123
Oct. 10, 2024 (KR) 10-2024-0138036

(51) Int. Cl. G06F 11/10; G11C 16/10; G11C 16/26; H03M 13/15

(52) U.S. Cl. CPC G06F 11/1068; G11C 16/102; G11C 16/26; H03M 13/1515

(57) ABSTRACT

A semiconductor device includes an error correction buffer circuit that generates an error correction signal when one of a first write operation and a second write operation is performed based on a command address, a first chip selection signal, a second chip selection signal, first data, and second data; a first data storage block that stores the first data when the first write operation is performed based on the command address, the first chip selection signal, and the second chip selection signal, a second data storage block that stores the second data when the second write operation is performed based on the command address, the first chip selection signal, and the second chip selection signal; and an error correction signal storage circuit that stores the error correction signal when one of the first write operation and the second write operation is performed based on the command address.

### CROSS-REFERENCE TO RELATED APPLICATIONS

The present application claims priority under 35 U.S.C. § 119(a) to Korean Patent Application number 10-2024-0019123 filed on Feb. 7, 2024, in the Korean Intellectual Property Office and Korean Patent Application number 10-2024-0138036 filed on Oct. 10, 2024, in the Korean Intellectual Property Office, the entire contents of which applications are incorporated herein by reference.

### BACKGROUND

### 1. Technical Field

The present disclosure relates to a semiconductor device and a semiconductor system including but not limited to data error correction.

### 2. Related Art

To correct one or more errors in received data, various block codes, such as Hamming codes, Bose-Chaudhuri-Hocquenghem (BCH) codes, and Reed-Solomon (RS) codes, are used. Hamming codes are frequently used during data transmission through a channel in a computer memory system because Hamming codes efficiently detect and correct single-bit errors. The BCH code is widely used in various fields, such as communication systems, storage devices, and computer networks because BCH codes can correct multiple errors and burst errors. RS codes are widely used in applications that require a high-level of error correction, such as satellite communications and wireless communication systems, because RS codes can achieve a high-level of error correction with a relatively small number of redundant or overhead bits.

### SUMMARY

In an embodiment, a semiconductor device may include an error correction buffer circuit configured to generate an error correction signal when one of a first write operation and a second write operation is performed based on a command address, a first chip selection signal, a second chip selection signal, first data, and second data; a first data storage block configured to store the first data when the first write operation is performed based on the command address, the first chip selection signal, and the second chip selection signal; a second data storage block configured to store the second data when the second write operation is performed based on the command address, the first chip selection signal, and the second chip selection signal; and an error correction signal storage circuit configured to store the error correction signal when one of the first write operation and the second write operation is performed based on the command address.

In an embodiment, a semiconductor device may include a first data storage block configured to store first data when a first write operation is performed based on a command address, a first chip selection signal, and a second chip selection signal; a second data storage block configured to store second data when a second write operation is performed based on the command address, the first chip selection signal, and the second chip selection signal; and an error correction signal storage circuit configured to store an error correction signal from a controller when one of the first write operation and the second write operation is performed based on the command address.

In an embodiment, a semiconductor device may include an error correction buffer circuit configured to generate a first error correction signal and a second error correction signal when at least one of a first write operation for first channel data and a second write operation for second channel data is performed based on a command address, a first chip selection signal, a second chip selection signal, the first channel data, and the second channel data; a first data storage block configured to store the first channel data when the first write operation is performed based on the command address, the first chip selection signal, and the second chip selection signal; a second data storage block configured to store the second channel data when the second write operation is performed based on the command address, the first chip selection signal, and the second chip selection signal; a first error correction signal storage block configured to store the first error correction signal when the first write operation is performed based on the command address, the first chip selection signal, and the second chip selection signal; and a second error correction signal storage block configured to store the second error correction signal when the second write operation is performed based on the command address, the first chip selection signal, and the second chip selection signal.

In an embodiment, a semiconductor device may include a first data storage block configured to store first data when a first write operation is performed; a second data storage block configured to store second data when a second write operation is performed; and an error correction signal storage circuit configured to store error correction signals that correct the first data stored in the first data storage block and the second data stored in the second data storage block.

### BRIEF DESCRIPTION OF THE DRAWINGS

FIG. 1 is a block diagram illustrating a semiconductor system according to an embodiment of the present disclosure.

FIG. 2 is a block diagram illustrating an embodiment of a semiconductor device according to the present disclosure.

FIG. 3 is a block diagram illustrating an embodiment of a semiconductor device according to the present disclosure.

FIG. 4 is a block diagram illustrating a semiconductor system according to an embodiment of the present disclosure.

FIG. 5 is a block diagram illustrating an embodiment of a semiconductor device according to the present disclosure.

FIG. 6 is a block diagram illustrating a semiconductor system according to an embodiment of the present disclosure.

FIG. 7 is a block diagram illustrating an embodiment of a semiconductor device according to the present disclosure.

FIG. 8 is a block diagram illustrating an electronic system according to an embodiment of the present disclosure.

FIG. 9 is a block diagram illustrating an electronic system according to an embodiment of the present disclosure.

### DETAILED DESCRIPTION

When one element is identified as “connected” to another element, the elements may be connected directly or through an intervening element between the elements. When two elements are identified as “directly connected,” one element is directly connected to the other element without an intervening element between the two elements.

Terms such as “first” and “second” are used to distinguish between various elements and do not imply size, order, priority, quantity, or importance of the elements. For example, a first element may be referred to as a second element in one example, and the second element may be referred to as a first element in another example.

Embodiments of the present disclosure are described in detail with reference to the accompanying drawings. Specific structural or functional descriptions of embodiments are provided as examples for illustrative purposes to describe concepts that are disclosed in the present application. Examples or embodiments in accordance with the concepts may be carried out in various forms, and the scope of the present disclosure is not limited to the examples or embodiments described in this specification.

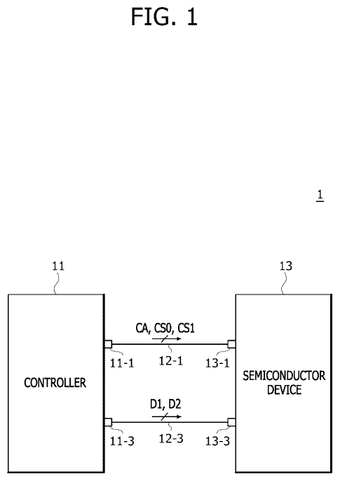

FIG. 1 is a block diagram illustrating a semiconductor system 1 according to an embodiment of the present disclosure. As illustrated in FIG. 1, the semiconductor system 1 includes a controller 11 and a semiconductor device 13.

The controller 11 includes a first control pin 11-1 and a second control pin 11-3. The semiconductor device 13 includes a first device pin 13-1 and a second device pin 13-3. The controller 11 transmits a command address CA, a first chip selection signal CS0, and a second chip selection signal CS1 to the semiconductor device 13 through a first transmission line 12-1 connected between the first control pin 11-1 and the first device pin 13-1. In an embodiment, the command address CA includes multiple bits that correspond to a command and an address. Depending on the quantity of bits included in each of the command address CA, the first chip selection signal CS0, and the second chip selection signal CS1, a plurality of first control pins 11-1, a plurality of first transmission lines 12-1, and a plurality of first device pins 13-1 may be included. The controller 11 transmits first data D1 and second data D2 to the semiconductor device 13 through a second transmission line 12-3 connected between the second control pin 11-3 and the second device pin 13-3. Depending on the quantity of bits included in the first data D1 and the second data D2, a plurality of second control pins 11-3, a plurality of second device pins 13-3, and a plurality of second transmission lines 12-3 may be included.

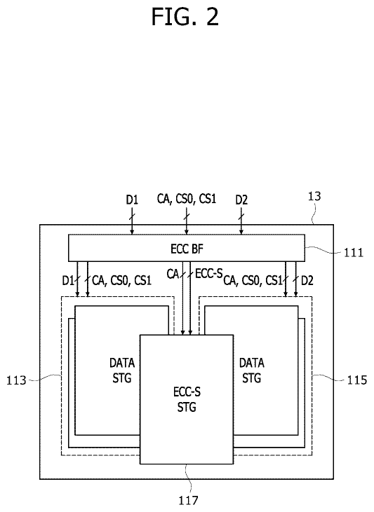

The semiconductor device 13 receives the command address CA, the first chip selection signal CS0, the second chip selection signal CS1, and the first data D1 and the second data D2 from the controller 11 that is electrically connected to the semiconductor device 13. The semiconductor device 13 generates an error correction signal, such as ECC-S in FIG. 2, that corrects one or more errors received in the first data D1 and the second data D2 based on the command address CA, the first chip selection signal CS0, and the second chip selection signal CS1 and internally stores the error correction signal. The semiconductor device 13 can improve the reliability of the first data D1 and the second data D2 when the semiconductor device 13 corrects one or more errors received in the first data D1 and the second data D2 based on the error correction signal.

FIG. 2 is a block diagram illustrating an embodiment of the semiconductor device 13, for example, as illustrated in FIG. 1.

As illustrated in FIG. 2, the semiconductor device 13 includes an error correction buffer circuit (ECC BF) 111, a first data storage block 113, a second data storage block 115, and an error correction signal storage circuit (ECC-S STG) 117.

The error correction buffer circuit 111 receives the command address CA, the first chip selection signal CS0, the second chip selection signal CS1, and the first data D1 and the second data D2 from the controller 11 that is electrically connected to the error correction buffer circuit 111. The error correction buffer circuit 111 generate the error correction signal ECC-S from the first data D1 and the second data D2 when at least one of a first write operation for the first data storage block 113 and a second write operation for the second data storage block 115 is performed based on the command address CA, the first chip selection signal CS0, and the second chip selection signal CS1. The error correction buffer circuit 111 generates the error correction signal ECC-S including information identifying one or more errors received in the first data D1 and the second data D2 based on an error correction code implemented, for example, with an H-matrix or an RS code. The error correction signal ECC-S may include one or more symbols or a syndrome including information identifying the location of one or more errors in the data. The error correction buffer circuit 111 outputs the command address CA, the first chip selection signal CS0, the second chip selection signal CS1, the first data D1 and the second data D2, and the error correction signal ECC-S.

The first data storage block 113 receives the first data D1, the command address CA, the first chip selection signal CS0, and the second chip selection signal CS1 from the error correction buffer circuit 111 that is electrically connected to the first data storage block 113. The first data storage block 113 stores the first data D1 when the first write operation is performed based on the command address CA, the first chip selection signal CS0, and the second chip selection signal CS1. The first data storage block 113 includes a plurality of data storage circuits DATA STG. Each of the plurality of data storage circuits DATA STG of the first data storage block 113 stores the first data D1 when selectively activated by the first chip selection signal CS0 and the second chip selection signal CS1.

The second data storage block 115 receives the second data D2, the command address CA, the first chip selection signal CS0, and the second chip selection signal CS1 from the error correction buffer circuit 111 that is electrically connected to the second data storage block 115. The second data storage block 115 stores the second data D2 when the second write operation is performed based on the command address CA, the first chip selection signal CS0, and the second chip selection signal CS1. The second data storage block 115 includes a plurality of data storage circuits DATA STG. Each of the plurality of data storage circuits DATA STG of the second data storage block 115 stores the second data D2 when selectively activated by the first chip selection signal CS0 and the second chip selection signal CS1.

The error correction signal storage circuit 117 receives the command address CA and the error correction signal ECC-S from the error correction buffer circuit 111 that is electrically connected to the error correction signal storage circuit 117. The error correction signal storage circuit 117 stores the error correction signal ECC-S based on the command address CA. The error correction signal storage circuit 117 stores the error correction signal ECC-S when at least one of the first write operation and the second write operation is performed based on the command address CA. The error correction signal storage circuit 117 outputs the error correction signal ECC-S to correct one or more errors received in the first data D1 output by the first data storage block 113 when a read operation is performed on the first data storage block 113. The error correction signal storage circuit 117 outputs the error correction signal ECC-S to correct one or more errors received in the second data D2 output by the second data storage block 115 when a read operation is performed on the second data storage block 115.

The semiconductor device 13 can improve the reliability of the first data D1 and the second data D2 when the semiconductor device 13 includes the error correction signal storage circuit 117 that stores the error correction signal ECC-S used to correct one or more errors received in the first data D1 and the second data D2 stored in the first data storage block 113 and the second data storage block 115, respectively. The semiconductor device 13 may have a reduced layout area because the error correction signal storage circuit 117 that stores the error correction signal ECC-S is shared by the first data storage block 113 and the second data storage block 115.

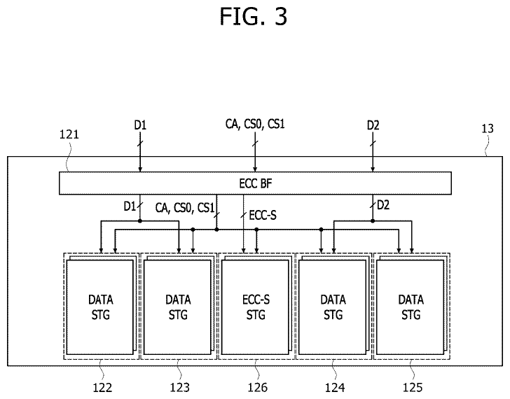

FIG. 3 is a block diagram illustrating an embodiment of the semiconductor device 13, for example, as illustrated in FIG. 1.

As illustrated in FIG. 3, the semiconductor device 13 includes an error correction buffer circuit (ECC BF) 121, a first data storage block 122, a second data storage block 123, a third data storage block 124, a fourth data storage block 125, and an error correction signal storage block (ECC-S STG) 126.

The error correction buffer circuit 121 receives the command address CA, the first chip selection signal CS0, the second chip selection signal CS1, and the first data D1 and the second data D2 from the controller 11 that is electrically connected to the error correction buffer circuit 121. The error correction buffer circuit 121 generates the error correction signal ECC-S from the first data D1 and the second data D2 when at least one of a first write operation for the first data storage block 122, a second write operation for the second data storage block 123, a third write operation for the third data storage block 124, and a fourth write operation for the fourth data storage block 125 is performed based on the command address CA, the first chip selection signal CS0, and the second chip selection signal CS1. The error correction buffer circuit 121 generates the error correction signal ECC-S including information identifying one or more errors received in the first data D1 and the second data D2 based on an error correction code implemented, for example, with an H-matrix or an RS code. The error correction signal ECC-S may include one or more symbols or a syndrome including information identifying the location of one or more errors in the data. The error correction buffer circuit 121 outputs the command address CA, the first chip selection signal CS0, the second chip selection signal CS1, the first data D1 and the second data D2, and the error correction signal ECC-S.

The first data storage block 122 receives the first data D1, the command address CA, the first chip selection signal CS0, and the second chip selection signal CS1 from the error correction buffer circuit 121 that is electrically connected to the first data storage block 122. The first data storage block 122 stores the first data D1 when the first write operation is performed based on the command address CA, the first chip selection signal CS0, and the second chip selection signal CS1. The first data storage block 122 includes a plurality of data storage circuits DATA STG. Each of the plurality of data storage circuits DATA STG stores the first data D1 when selectively activated by the first chip selection signal CS0 and the second chip selection signal CS1.

The second data storage block 123 receives the first data D1, the command address CA, the first chip selection signal CS0, and the second chip selection signal CS1 from the error correction buffer circuit 121 that is electrically connected to the second data storage block 123. The second data storage block 123 stores the first data D1 when the second write operation is performed based on the command address CA, the first chip selection signal CS0, and the second chip selection signal CS1. The second data storage block 123 includes a plurality of data storage circuits DATA STG. Each of the plurality of data storage circuits DATA STG stores the first data D1 when selectively activated by the first chip selection signal CS0 and the second chip selection signal CS1.

The third data storage block 124 receives the second data D2, the command address CA, the first chip selection signal CS0, and the second chip selection signal CS1 from the error correction buffer circuit 121 that is electrically connected to the third data storage block 124. The third data storage block 124 stores the second data D2 when the third write operation is performed based on the command address CA, the first chip selection signal CS0, and the second chip selection signal CS1. The third data storage block 124 includes a plurality of data storage circuits DATA STG. Each of the plurality of data storage circuits DATA STG stores the second data D2 when selectively activated by the first chip selection signal CS0 and the second chip selection signal CS1.

The fourth data storage block 125 receives the second data D2, the command address CA, the first chip selection signal CS0, and the second chip selection signal CS1 from the error correction buffer circuit 121 that is electrically connected to the fourth data storage block 125. The fourth data storage block 125 stores the second data D2 when the fourth write operation is performed based on the command address CA, the first chip selection signal CS0, and the second chip selection signal CS1. The fourth data storage block 125 includes a plurality of data storage circuits DATA STG. Each of the plurality of data storage circuits DATA STG stores the second data D2 when selectively activated by the first chip selection signal CS0 and the second chip selection signal CS1.

The error correction signal storage block 126 receives the command address CA, the first chip selection signal CS0, the second chip selection signal CS1, and the error correction signal ECC-S from the error correction buffer circuit 121 that is electrically connected to the error correction signal storage block 126. The error correction signal storage block 126 stores the error correction signal ECC-S, based on the command address CA, the first chip selection signal CS0, and the second chip selection signal CS1. The error correction signal storage block 126 stores the error correction signal ECC-S when at least one of the first write operation, the second write operation, the third write operation, and the fourth write operation is performed based on the command address CA, the first chip selection signal CS0, and the second chip selection signal CS1. The error correction signal storage block 126 includes a plurality of error correction signal storage circuits ECC-S STG. Each of the plurality of error correction signal storage circuits ECC-S STG stores the error correction signal ECC-S when selectively activated by the first chip selection signal CS0 and the second chip selection signal CS1. The error correction signal storage block 126 outputs the error correction signal ECC-S to correct one or more errors received in the first data D1 output by the first data storage block 113 when a read operation is performed on the first data storage block 122. The error correction signal storage block 126 outputs the error correction signal ECC-S to correct one or more errors received in the first data D1 output by the second data storage block 123 when a read operation is performed on the second data storage block 123. The error correction signal storage block 126 outputs the error correction signal ECC-S to correct one or more errors received in the second data D2 output by the third data storage block 124 when a read operation is performed on the third data storage block 124. The error correction signal storage block 126 outputs the error correction signal ECC-S to correct one or more errors received in the second data D2 output by the fourth data storage block 125 when a read operation is performed on the fourth data storage block 125.

The semiconductor device 13 can improve the reliability of the first data D1 and the second data D2 when the semiconductor device 13 includes an error correction signal storage block 126 that stores the error correction signal ECC-S used to correct one or more errors received in the first data D1 and the second data D2 in the first data storage block 122, the second data storage block 123, the third data storage block 124, and the fourth data storage block 125. The semiconductor device 13 may have a reduced layout area because the error correction signal storage block 126 that stores the error correction signal ECC-S is shared by the first data storage block 122, the second data storage block 123, the third data storage block 124, and the fourth data storage block 125.

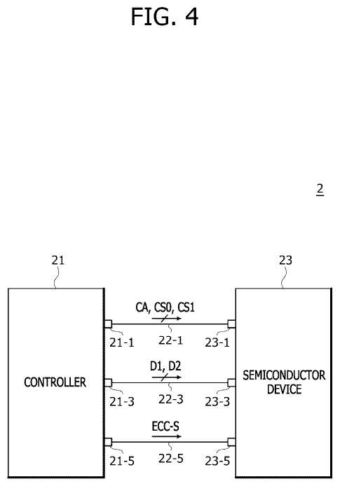

FIG. 4 is a block diagram illustrating a semiconductor system 2 according to an embodiment of the present disclosure. As illustrated in FIG. 4, the semiconductor system 2 includes a controller 21 and a semiconductor device 23.

The controller 21 includes a first control pin 21-1, a second control pin 21-3, and a third control pin 21-5. The semiconductor device 23 includes a first device pin 23-1, a second device pin 23-3, and a third device pin 23-5. The controller 21 transmits a command address CA, a first chip selection signal CS0, and a second chip selection signal CS1 to the semiconductor device 23 through a first transmission line 22-1 connected between the first control pin 21-1 and the first device pin 23-1. In an embodiment, the command address CA includes multiple bits that correspond to a command and an address. Depending on the quantity of bits included in each of the command address CA, the first chip selection signal CS0, and the second chip selection signal CS1, a plurality of first control pins 21-1, a plurality of first transmission lines 22-1, and a plurality of first device pins 23-1 may be included. The controller 21 transmits the first data D1 and the second data D2 to the semiconductor device 23 through a second transmission line 22-3 that is connected between the second control pin 21-3 and the second device pin 23-3. Depending on the quantity of bits included in each of the first data D1 and the second data D2, a plurality of second control pins 21-3, a plurality of second device pins 23-3, and a plurality of second transmission lines 22-3 may be included. The controller 21 transmits an error correction signal ECC-S to the semiconductor device 23 through a second transmission line 22-5 connected between the third control pin 21-5 and the third device pin 23-5. The controller 21 generates the error correction signal ECC-S including information identifying one or more errors received in the first data D1 and the second data D2 based on an error correction code implemented, for example, with an H-matrix or an RS code. The error correction signal ECC-S may include one or more symbols or a syndrome including information identifying the location of one or more errors in the data.

The semiconductor device 23 receives the command address CA, the first chip selection signal CS0, the second chip selection signal CS1, the first data D1 and the second data D2, and the error correction signal ECC-S from the controller 21 that is electrically connected to the semiconductor device 23. The semiconductor device 23 internally stores the error correction signal ECC-S, based on the command address CA, the first chip selection signal CS0, and the second chip selection signal CS1. The semiconductor device 23 can improve the reliability of the first data D1 and the second data D2 when one or more errors received in the first data D1 and the second data D2 are corrected based on the error correction signal ECC-S.

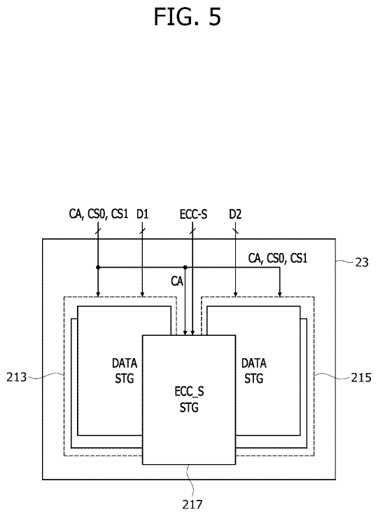

FIG. 5 is a block diagram illustrating an embodiment of the semiconductor device 23, for example, as illustrated in FIG. 4.

As illustrated in FIG. 5, the semiconductor device 23 includes a first data storage block 213, a second data storage block 215, and an error correction signal storage circuit ECC-S STG 217.

The first data storage block 213 stores the first data D1 when a first write operation is performed on the first data storage block 213 based on the command address CA, the first chip selection signal CS0, and the second chip selection signal CS1. The first data storage block 213 includes a plurality of data storage circuits DATA STG. Each of the plurality of data storage circuits DATA STG of the first data storage block 213 stores the first data D1 when selectively activated by the first chip selection signal CS0 and the second chip selection signal CS1.

The second data storage block 215 stores the second data D2 when a second write operation is performed on the second data storage block 215 based on the command address CA, the first chip selection signal CS0, and the second chip selection signal CS1. The second data storage block 215 includes a plurality of data storage circuits DATA STG. Each of the plurality of data storage circuits DATA STG of the second data storage block 215 stores the second data D2 when selectively activated by the first chip selection signal CS0 and the second chip selection signal CS1.

The error correction signal storage circuit 217 stores the error correction signal ECC-S based on the command address CA. The error correction signal storage circuit 217 stores the error correction signal ECC-S when at least one of the first write operation and the second write operation is performed based on the command address CA. The error correction signal storage circuit 217 outputs the error correction signal ECC-S to correct one or more errors received in the first data D1 output by the first data storage block 213 when a read operation is performed on the first data storage block 213. The error correction signal storage circuit 217 outputs the error correction signal ECC-S to correct one or more errors received in the second data D2 output by the second data storage block 215 when a read operation is performed on the second data storage block 215.

The semiconductor device 23 can improve the reliability of the first data D1 and the second data D2 when the semiconductor device 23 includes the error correction signal storage circuit 217 that stores the error correction signal ECC-S used to correct one or more errors received in the first data D1 and the second data D2 stored in the first data storage block 213 and the second data storage block 215, respectively. The semiconductor device 23 may have a reduced layout area because the error correction signal storage circuit 217 that stores the error correction signal ECC-S is shared by the first data storage block 213 and the second data storage block 215.

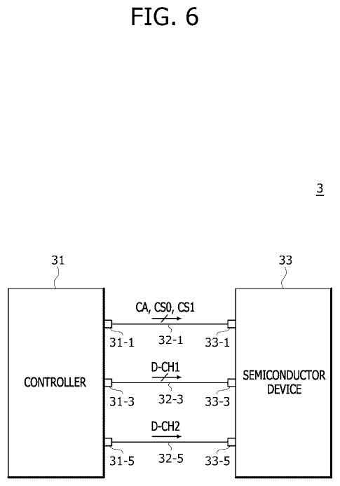

FIG. 6 is a block diagram illustrating a semiconductor system 3 according to an embodiment of the present disclosure. As illustrated in FIG. 6, the semiconductor system 3 includes a controller 31 and a semiconductor device 33.

The controller 31 includes a first control pin 31-1, a second control pin 31-3, and a third control pin 31-5. The semiconductor device 33 includes a first device pin 33-1, a second device pin 33-3, and a third device pin 33-5. The controller 31 transmits a command address CA, a first chip selection signal CS0, and a second chip selection signal CS1 to the semiconductor device 33 through a first transmission line 32-1 connected between the first control pin 31-1 and the first device pin 33-1. In an embodiment, the command address CA includes multiple bits that correspond to a command and an address. Depending on the quantity of bits included in each of the command address CA, the first chip selection signal CS0, and the second chip selection signal CS1, a plurality of first control pins 31-1, a plurality of first transmission lines 32-1, and a plurality of first device pins 33-1 may be included. The controller 31 transmits first channel data D-CH1 to the semiconductor device 33 through a second transmission line 32-3 connected between the second control pin 31-3 and the second device pin 33-3. Depending on the quantity of bits of the first channel data D-CH1, a plurality of second control pins 31-3, a plurality of second device pins 33-3, and a plurality of second transmission lines 32-3 may be included. The controller 31 transmits second channel data D-CH2 to the semiconductor device 33 through a third transmission line 32-5 connected between the third control pin 31-5 and the third device pin 33-5. Depending on the quantity of bits included in the second channel data D-CH2, a plurality of third control pins 31-5, a plurality of third device pins 33-5, and a plurality of third transmission lines 32-5 may be included.

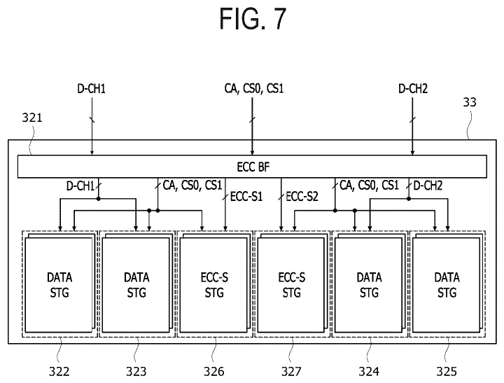

The semiconductor device 33 receives the command address CA, the first chip selection signal CS0, the second chip selection signal CS1, the first channel data D-CH1, and the second channel data D-CH2 from the controller 31 that is electrically connected to the semiconductor device 33. The semiconductor device 33 generate error correction signals, such as ECC-S1 and ECC-S2 in FIG. 7, that corrects one or more errors received in the first channel data D-CH1 and the second channel data D-CH2 based on the command address CA, the first chip selection signal CS0, and the second chip selection signal CS1 and internally stores the error correction signals. The semiconductor device 33 can improve the reliability of the first channel data D-CH1 and the second channel data D-CH2 when the semiconductor device 33 corrects one or more errors received in the first channel data D-CH1 and the second channel data D-CH2 based on the error correction signals.

FIG. 7 is a block diagram illustrating an embodiment of the semiconductor device 33, for example, as illustrated in FIG. 6.

As illustrated in FIG. 7, the semiconductor device 33 includes an error correction buffer circuit 321, a first data storage block 322, a second data storage block 323, a third data storage block 324, a fourth data storage block 325, a first error correction signal storage block 326, and a second error correction signal storage block 327.

The error correction buffer circuit 321 receives the command address CA, the first chip selection signal CS0, the second chip selection signal CS1, the first channel data D-CH1, and the second channel data D-CH2 from the controller 31. The error correction buffer circuit 321 generates a first error correction signal ECC-S1 and a second error correction signal ECC-S2 from the first channel data D-CH1 and the second channel data D-CH2, respectively, when at least one of a first write operation for the first data storage block 322, a second write operation for the second data storage block 323, a third write operation for the third data storage block 324, and a fourth write operation for the fourth data storage block 325 is performed based on the command address CA, the first chip selection signal CS0, and the second chip selection signal CS1. The error correction buffer circuit 321 generates the first error correction signal ECC-S1 including information identifying one or more errors received in the first channel data D-CH1 and the second error correction signal ECC-S2 including information identifying one or more errors received in the second channel data D-CH2 based on an error correction code implemented, for example, with an H-matrix or an RS code. Each of the first error correction signal ECC-S1 and the second error correction signal ECC-S2 may include one or more symbols or a syndrome including information identifying the location of one or more errors in the data. The error correction buffer circuit 321 outputs the command address CA, the first chip selection signal CS0, the second chip selection signal CS1, the first channel data D-CH1, the second channel data D-CH2, and the error correction signal ECC-S.

The first data storage block 322 receives the first channel data D-CH1, the command address CA, the first chip selection signal CS0, and the second chip selection signal CS1 from the error correction buffer circuit 321 that is electrically connected to the first data storage block 322. The first data storage block 322 stores the first channel data D-CH1 when the first write operation is performed based on the command address CA, the first chip selection signal CS0, and the second chip selection signal CS1. The first data storage block 322 includes a plurality of data storage circuits DATA STG. Each of the plurality of data storage circuits DATA STG in the first data storage block 322 stores the first channel data D-CH1 when selectively activated by the first chip selection signal CS0 and the second chip selection signal CS1.

The second data storage block 323 receives the first channel data D-CH1, the command address CA, the first chip selection signal CS0, and the second chip selection signal CS1 from the error correction buffer circuit 321 that is electrically connected to the second data storage block 323. The second data storage block 323 stores the first channel data D-CH1 when the second write operation is performed based on the command address CA, the first chip selection signal CS0, and the second chip selection signal CS1. The second data storage block 323 includes a plurality of data storage circuits DATA STG. Each of the plurality of data storage circuits DATA STG in the second data storage block 323 stores the first channel data D-CH1 when selectively activated by the first chip selection signal CS0 and the second chip selection signal CS1.

The third data storage block 324 receives the second channel data D-CH2, the command address CA, the first chip selection signal CS0, and the second chip selection signal CS1 from the error correction buffer circuit 321 that is electrically connected to the third data storage block 324. The third data storage block 324 stores the second channel data D-CH2 when the third write operation is performed based on the command address CA, the first chip selection signal CS0, and the second chip selection signal CS1. The third data storage block 324 includes a plurality of data storage circuits DATA STG. Each of the plurality of data storage circuits DATA STG in the third data storage block 324 stores the second channel data D-CH2 when selectively activated by the first chip selection signal CS0 and the second chip selection signal CS1.

The fourth data storage block 325 receives the second channel data D-CH2, the command address CA, the first chip selection signal CS0, and the second chip selection signal CS1 from the error correction buffer circuit 321 that is electrically connected to the fourth data storage block 325. The fourth data storage block 325 stores the second channel data D-CH2 when the fourth write operation is performed based on the command address CA, the first chip selection signal CS0, and the second chip selection signal CS1. The fourth data storage block 325 includes a plurality of data storage circuits DATA STG. Each of the plurality of data storage circuits DATA STG in the fourth data storage block 325 stores the second channel data D-CH2 when selectively activated by the first chip selection signal CS0 and the second chip selection signal CS1.

The first error correction signal storage block 326 receives the command address CA, the first chip selection signal CS0, the second chip selection signal CS1, and the first error correction signal ECC-S1 from the error correction buffer circuit 321 that is electrically connected to the first error correction signal storage block 326. The first error correction signal storage block 326 stores the first error correction signal ECC-S1 based on the command address CA, the first chip selection signal CS0, and the second chip selection signal CS1. The first error correction signal storage block 326 stores the first error correction signal ECC-S1 when at least one of the first write operation, the second write operation, the third write operation, and the fourth write operation is performed based on the command address CA, the first chip selection signal CS0, and the second chip selection signal CS1. The first error correction signal storage block 326 includes a plurality of error correction signal storage circuits ECC-S STG. Each of the plurality of error correction signal storage circuits ECC-S STG in the first error correction signal storage block 326 stores the first error correction signal ECC-S1 when selectively activated by the first chip selection signal CS0 and the second chip selection signal CS1. The first error correction signal storage block 326 outputs the first error correction signal ECC-S1 to correct one or more errors received in the first channel data D-CH1 output by the first data storage block 322 when the read operation is performed on the first data storage block 322. The error correction signal storage block 326 outputs the first error correction signal ECC-S1 to correct one or more errors received in the first channel data D-CH1 output by the second data storage block 323 when a read operation is performed on the second data storage block 323.

The second error correction signal storage block 327 receives the command address CA, the first chip selection signal CS0, the second chip selection signal CS1, and the second error correction signal ECC-S2 from the error correction buffer circuit 321 that is electrically connected to the second error correction signal storage block 327. The second error correction signal storage block 327 stores the second error correction signal ECC-S2, based on the command address CA, the first chip selection signal CS0, and the second chip selection signal CS1. The second error correction signal storage block 327 stores the second error correction signal ECC-S2 when at least one of the first write operation, the second write operation, the third write operation, and the fourth write operation is performed based on the command address CA, the first chip selection signal CS0, and the second chip selection signal CS1. The second error correction signal storage block 327 includes a plurality of error correction signal storage circuits ECC-S STG. Each of the plurality of error correction signal storage circuits ECC-S STG of the second error correction signal storage block 327 stores the second error correction signal ECC-S2 when selectively activated by the first chip selection signal CS0 and the second chip selection signal CS1. The error correction signal storage block 326 outputs the second error correction signal ECC-S2 to correct one or more errors received in the second channel data D-CH2 output by the third data storage block 324 when a read operation is performed on the third data storage block 324. The error correction signal storage block 326 outputs the second error correction signal ECC-S2 to correct one or more errors received in the second channel data D-CH2 output by the fourth data storage block 325 when a read operation is performed on the fourth data storage block 325.

The semiconductor device 33 can improve the reliability of the first channel data D-CH1 and the second channel data D-CH2 when the semiconductor device 33 includes the first error correction signal storage block 326 that stores the first error correction signal ECC-S1 used to correct one or more errors received in the first channel data D-CH1 stored in the first data storage block 322 and the second data storage block 323 and includes the second error correction signal storage block 327 that stores the second error correction signal ECC-S2 used to correct one or more errors received in the second channel data D-CH2 stored in the third data storage block 324 and the fourth data storage block 325. The semiconductor device 33 may have a reduced layout area because the first error correction signal storage block 326 that stores the first error correction signal ECC-S1 is shared by the first data storage block 322 and the second data storage block 323, and the second error correction signal storage block 327 that stores the second error correction signal ECC-S2 is shared by the third data storage block 324 and the fourth data storage block 325.

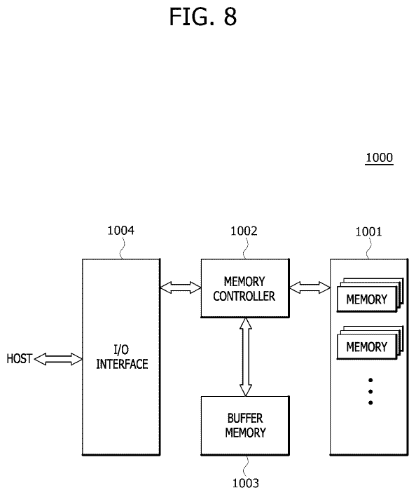

The semiconductor system 1 described with reference to FIG. 1, the semiconductor system 2 described with reference to FIG. 4, and the semiconductor system 3 described with reference to FIG. 6 may be incorporated in an electronic system including a memory system, a graphic system, a computing system, and a mobile system. For example, referring to FIG. 8, an electronic system 1000 according to an embodiment of the present disclosure includes a data storage unit 1001, a memory controller 1002, buffer memory 1003, and an input and output I/O interface 1004.

The data storage unit 1001 stores data (not illustrated) output from the memory controller 1002 based on a control signal from the memory controller 1002, reads the stored data, and outputs the read data to the memory controller 1002. The data storage unit 1001 may include nonvolatile memory capable of continuously storing data without losing data although power is interrupted. The nonvolatile memory may be implemented with flash memory such as NOR flash memory or NAND flash memory, phase change random access memory (PRAM), resistive random access memory (RRAM), spin transfer torque random access memory (STTRAM), or magnetic random access memory (MRAM).

The memory controller 1002 receives and decodes an instruction or command from an external device, for example, a host device, through the I/O interface 1004 and controls the input of data to and output of data from the data storage unit 1001 and the buffer memory 1003 based on the decoded command. In FIG. 8, the memory controller 1002 is illustrated as one block, but the memory controller 1002 may include a separate controller that controls the data storage unit 1001 and a controller that controls the buffer memory 1003, such as volatile memory. The memory controller 1002 may be implemented with the controller 11 described with reference to FIG. 1, the controller 21 described with reference to FIG. 4, or the controller 31 described with reference to FIG. 6.

The buffer memory 1003 temporarily stores data processed by the memory controller 1002, such as data input to and output from the data storage unit 1001. The buffer memory 1003 stores data output from the memory controller 1002 based on a control signal. The buffer memory 1003 may be implemented with the semiconductor device 13 described with reference to FIG. 1, the semiconductor device 23 described with reference to FIG. 4, or the semiconductor device 33 described with reference to FIG. 6. The buffer memory 1003 reads data stored in the buffer memory 1003 and outputs the read data to the memory controller 1002. The buffer memory 1003 may include volatile memory, such as dynamic random access memory (DRAM), mobile DRAM, or static random access memory (SRAM). The buffer memory 1003 may improve data reliability by including one or more error correction signal storage blocks one or more error correction signals that correct one or more errors received in the data as described.

The I/O interface 1004 provides a physical connection between the memory controller 1002 and an external device or a host such that the memory controller 1002 receives control signals that control the input and output of data from the external device and exchange data with the external device. The I/O interface 1004 may utilize one or more of various interface protocols, such as universal serial bus (USB), multi-media card (MMC), peripheral component interconnect-express (PCI-E), small computer system interface (SCSI), serial attached SCSI (SAS), serial advanced technology attachment (SATA), parallel advanced technology attachment (PATA), enhanced small disk interface (ESDI), and integrated drive electronics (IDE).

The electronic system 1000 may be used as an auxiliary storage device of a host device or an external storage device. The electronic system 1000 may include a solid state disk (SSD), a USB memory, a secure digital (SD) card, a mini secure digital (mSD) card, a micro SD card, a secure digital high capacity (SDHC) card, a memory stick card, a smart media (SM) card, a MMC, an embedded MMC (eMMC), and a compact flash (CF) card.

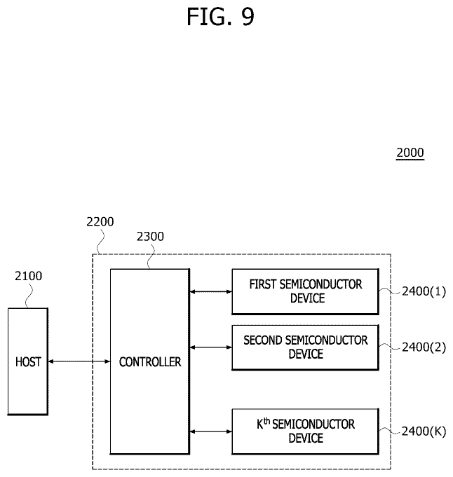

FIG. 9 is a block diagram illustrating an electronic system 2000 according to an embodiment of the present disclosure. As illustrated in FIG. 9, the electronic system 2000 includes a host 2100 and a semiconductor system 2200.

The host 2100 and the semiconductor system 2200 may mutually transmit signals by using an interface protocol. The interface protocol that is used between the host 2100 and the semiconductor system 2200 includes MMC, ESDI, IDE, PCI-E, advanced technology attachment (ATA), SATA, PATA, SAS, and USB.

The semiconductor system 2200 includes a controller 2300 and semiconductor devices 2400(1:K).

The controller 2300 may be implemented with the controller 11 described with reference to FIG. 1, the controller 21 described with reference to FIG. 4, or the controller 31 described with reference to FIG. 6. Each of the semiconductor devices 2400(1:K) may be implemented with the semiconductor device 13 described with reference to FIG. 1, the semiconductor device 23 described with reference to FIG. 4, or the semiconductor device 33 described with reference to FIG. 6. The semiconductor devices 2400(1:K) may be implemented with one or more of dynamic random access memory (DRAM), phase change random access memory (PRAM), resistive random access memory (RRAM), magnetic random access memory (MRAM), and ferroelectric random access memory (FRAM). The semiconductor devices 2400(1:K) may improve data reliability by including one or more error correction signal storage blocks one or more error correction signals that correct one or more errors received in the data as described.

Concepts are disclosed in conjunction with examples and embodiments. Those skilled in the art will understand that various modifications, additions, and substitutions are possible without departing from the scope and technical concepts of the present disclosure. The embodiments disclosed in the present specification should be considered from an Illustrative standpoint and not a restrictive standpoint. Therefore, the scope of the present disclosure is not limited to the above descriptions. All changes within the meaning and range of equivalency of the claims are included within their scope.

What is claimed is:

1. A semiconductor device comprising:
an error correction buffer circuit configured to generate an error correction signal when one of a first write operation and a second write operation is performed based on a command address, a first chip selection signal, a second chip selection signal, first data, and second data;
a first data storage block configured to store the first data when the first write operation is performed based on the command address, the first chip selection signal, and the second chip selection signal;
a second data storage block configured to store the second data when the second write operation is performed based on the command address, the first chip selection signal, and the second chip selection signal; and
an error correction signal storage circuit configured to store the error correction signal when one of the first write operation and the second write operation is performed based on the command address.

2. The semiconductor device of claim 1, wherein the error correction buffer circuit generates the error correction signal based on an error correction code and comprising information identifying an error received among the first data and the second data.

3. The semiconductor device of claim 1, wherein:
the first data storage block comprises a plurality of data storage circuits; and
each of the plurality of data storage circuits stores the first data when selectively activated by the first chip selection signal and the second chip selection signal.

4. The semiconductor device of claim 1, wherein:
the second data storage block comprises a plurality of data storage circuits, and
each of the plurality of data storage circuits stores the second data when selectively activated by the first chip selection signal and the second chip selection signal.

5. The semiconductor device of claim 1, wherein the error correction signal storage circuit outputs the error correction signal to correct an error received in the first data output by the first data storage block when a read operation is performed on the first data storage block.

6. The semiconductor device of claim 1, wherein the error correction signal storage circuit outputs the error correction signal to correct an error received in the second data output by the second data storage block when a read operation is performed on the second data storage block.

7. A semiconductor device comprising:
a first data storage block configured to store first data when a first write operation is performed based on a command address, a first chip selection signal, and a second chip selection signal;
a second data storage block configured to store second data when a second write operation is performed based on the command address, the first chip selection signal, and the second chip selection signal; and
an error correction signal storage circuit configured to store an error correction signal from a controller when one of the first write operation and the second write operation is performed based on the command address.

8. The semiconductor device of claim 7, wherein:
the first data storage block comprises a plurality of data storage circuits; and
each of the plurality of data storage circuits stores the first data when selectively activated by the first chip selection signal and the second chip selection signal.

9. The semiconductor device of claim 7, wherein:
the second data storage block comprises a plurality of data storage circuits; and
each of the plurality of data storage circuits stores the second data when selectively activated by the first chip selection signal and the second chip selection signal.

10. The semiconductor device of claim 7, wherein the error correction signal storage circuit outputs the error correction signal to correct an error received in the first data output by the first data storage block when a read operation is performed on the first data storage block.

11. The semiconductor device of claim 7, wherein the error correction signal storage circuit outputs the error correction signal to correct an error received in the second data output by the second data storage block when a read operation is performed on the second data storage block.

12. A semiconductor device comprising:
an error correction buffer circuit configured to generate a first error correction signal and a second error correction signal when one of a first write operation for first channel data and a second write operation for second channel data is performed based on a command address, a first chip selection signal, a second chip selection signal, the first channel data, and the second channel data;
a first data storage block configured to store the first channel data when the first write operation is performed based on the command address, the first chip selection signal, and the second chip selection signal;
a second data storage block configured to store the second channel data when the second write operation is performed based on the command address, the first chip selection signal, and the second chip selection signal;
a first error correction signal storage block configured to store the first error correction signal when the first write operation is performed based on the command address, the first chip selection signal, and the second chip selection signal; and
a second error correction signal storage block configured to store the second error correction signal when the second write operation is performed based on the command address, the first chip selection signal, and the second chip selection signal.

13. The semiconductor device of claim 12, wherein the error correction buffer circuit receives the first channel data transmitted through a first transmission line from a controller and the second channel data transmitted through a second transmission line from the controller.

14. The semiconductor device of claim 12, wherein the error correction buffer circuit:
generates the first error correction signal based on a first error correction code comprising information identifying a location of an error received in the first channel data; and
generates the second error correction signal based on a second error correction code comprising information identifying a location of an error received in the second channel data.

15. The semiconductor device of claim 12, wherein:
the first data storage block comprises a plurality of data storage circuits; and
each of the plurality of data storage circuits stores the first channel data when selectively activated by the first chip selection signal and the second chip selection signal.

16. The semiconductor device of claim 12, wherein:
the second data storage block comprises a plurality of data storage circuits; and
each of the plurality of data storage circuits stores the second channel data when selectively activated by the first chip selection signal and the second chip selection signal.

17. The semiconductor device of claim 12, wherein the first error correction signal storage block outputs the first error correction signal to correct an error received in the first channel data output by the first data storage block when a read operation is performed on the first data storage block.

18. The semiconductor device of claim 12, wherein the second error correction signal storage block outputs the second error correction signal to correct an error received in the second channel data output by the second data storage block when a read operation is performed on the second data storage block.

19. A semiconductor device comprising:
a first data storage block configured to store first data when a first write operation is performed;
a second data storage block configured to store second data when a second write operation is performed; and
an error correction signal storage circuit configured to store error correction signals that correct the first data stored in the first data storage block and the second data stored in the second data storage block.
